(19) United States
(12) Patent Application Publication
(10) Pub. No.: US 2009/0127672 A1
(43) Pub. Date: May 21, 2009

(54) SUSCEPTOR FOR EPITAXIAL LAYER FORMING APPARATUS, EPITAXIAL LAYER FORMING APPARATUS, EPITAXIAL WAFER, AND METHOD OF MANUFACTURING EPITAXIAL WAFER

(75) Inventor: Hideaki Kinbara, Tokyo (JP)

Correspondence Address: GREENBLUM & BERNSTEIN, P.L.C., 1950 ROLAND CLARKE PLACE, RESTON, VA, 20191, US

(73) Assignee: SUMCO CORPORATION, Tokyo (JP)

(21) Appl. No.: 12/261,511

(22) Filed: Oct. 30, 2008

(30) Foreign Application Priority Data
Oct. 31, 2007 (JP) 2007-284512

(51) Int. Cl. H01L 29/06; C23C 16/54; H01L 21/20

(52) U.S. Cl. 257/652; 118/725; 438/478; 257/E29.016; 257/E21.09

(57) ABSTRACT

A susceptor for epitaxial layer forming apparatus provided in a layer forming chamber of an epitaxial layer forming apparatus includes: a recessed portion which is provided to accommodate a semiconductor wafer therein and has an approximately circular shape in plan view; and a protruding portion which is provided in the recessed portion in order to support the semiconductor wafer and has an approximately circular shape in plan view. The diameter of the protruding portion is smaller than that of the recessed portion, and the diameter of the protruding portion is set to be a size allowing reaction gas supplied for vapor-phase growth reaction to circulate through an entire boundary between the protruding portion and the semiconductor wafer when the semiconductor wafer is placed in the recessed portion.

### BACKGROUND OF THE INVENTION

1. Field of the Invention

The present invention relates to a susceptor for epitaxial layer forming apparatus, an epitaxial layer forming apparatus, an epitaxial wafer, and a method of manufacturing an epitaxial wafer.

Priority is claimed on Japanese Patent Application No. 2007-284512, filed Oct. 31, 2007, the content of which is incorporated herein by reference.

2. Description of Related Art

Apparatuses having various structures which are different in a heating method or the shape of a susceptor have been proposed as epitaxial layer forming apparatuses for vapor-phase growth of an epitaxial layer onto a semiconductor wafer in the related art. Specifically, a vertical epitaxial layer forming apparatus which heats a susceptor on a circular flat plate from below, a single wafer type epitaxial layer forming apparatus which introduces a semiconductor wafer into a layer forming chamber one at a time such that the semiconductor wafer is placed horizontally on a susceptor and heats the semiconductor wafer from above and below of the semiconductor wafer, and a barrel type epitaxial layer forming apparatus disclosed in JP-A-2001-160538 which heats a barrel-shaped susceptor using a high-frequency coil on a side surface are known.

A susceptor in which a SiC film is coated on a surface of graphite is disposed in a layer forming chamber of each of the epitaxial layer forming apparatuses, and a circular recessed portion capable of accommodating a semiconductor wafer on which an epitaxial layer is made to grow is formed in the susceptor.

In such epitaxial layer forming apparatuses, the pressure of the layer forming chamber is lowered in a state where a semiconductor wafer on which an epitaxial layer is made to grow is accommodated in a recessed portion of the susceptor. The semiconductor wafer in the layer forming chamber is heated directly or indirectly using a heating unit, such as a lamp heater. At the same time, reaction gas is supplied to the layer forming chamber so that single crystal, polycrystalline, or amorphous solid, for example, a semiconductor such as silicon, an oxide, a nitride, metal, an alloy, and other compounds are deposited on a surface of the semiconductor wafer, thereby making an epitaxial layer grow.

In the known epitaxial layer forming apparatuses, the entire back surface of a semiconductor wafer is not necessarily in close contact with a bottom surface of the recessed portion of the susceptor because the semiconductor wafer is only placed in the recessed portion of the susceptor. Therefore, each of the known epitaxial layer forming apparatuses has a structure where a small amount of reaction gas may also turn and circulate to the back surface side of the semiconductor wafer. In this case, since the entire back surface of the semiconductor wafer is in contact with the bottom surface of the recessed portion, the reaction gas is easily in contact with a peripheral edge portion of the bottom surface rather than a middle portion of the bottom surface.

In the barrel type epitaxial layer forming apparatus, however, sufficient heat energy is not supplied to the back surface side of the semiconductor wafer since the semiconductor wafer is heated only from a top surface side, such that the back surface side of the semiconductor wafer is easily etched by a small amount of reaction gas turned.

Furthermore, in the single wafer type epitaxial layer forming apparatus, the semiconductor wafer is heated from above and below, but the semiconductor wafer does not directly face a lamp heater on the lower side since the semiconductor wafer is placed on the susceptor. Accordingly, similar to the barrel type epitaxial layer forming apparatus, sufficient heat energy is not supplied to the back surface side of the semiconductor wafer and the back surface of the semiconductor wafer is easily etched.

Thus, in the known epitaxial layer forming apparatuses, an epitaxial layer is formed on a top surface of a semiconductor wafer and a back surface of the semiconductor wafer, particularly a peripheral edge portion is etched. For this reason, the thickness of a peripheral edge portion of an epitaxial wafer which is a finished product is smaller than that of a middle portion, and the thickness variation in the entire epitaxial wafer increases.

The invention has been finalized in view of the above situation, and it is an object of the invention to provide a susceptor capable of reducing the thickness variation in the entire epitaxial wafer, an epitaxial layer forming apparatus including the susceptor, an epitaxial wafer with small variation in thickness, and a method of manufacturing an epitaxial wafer.

### SUMMARY OF THE INVENTION

In order to achieve the above object, the invention adopts the following configurations.

According to an aspect of the invention, a susceptor for epitaxial layer forming apparatus provided in a layer forming chamber of an epitaxial layer forming apparatus includes: a recessed portion which is provided to accommodate a semiconductor wafer therein and has an approximately circular shape in plan view; and a protruding portion which is provided in the recessed portion in order to support the semiconductor wafer and has an approximately circular shape in plan view. The diameter of the protruding portion is smaller than that of the recessed portion. The diameter of the protruding portion is set to be a size allowing reaction gas supplied for vapor-phase growth reaction to circulate through an entire boundary between the protruding portion and the semiconductor wafer when the semiconductor wafer is placed in the recessed portion.

In the susceptor for epitaxial layer forming apparatus according to the aspect of the invention, since the protruding portion is provided in the recessed portion that accommodates a semiconductor wafer therein and the diameter of the protruding portion is set to be a size allowing reaction gas supplied for vapor-phase growth reaction to circulate through the entire boundary between the protruding portion and the semiconductor wafer when the semiconductor wafer is placed in the recessed portion, the reaction gas can be exposed on the entire surface of the semiconductor wafer facing the protruding portion when an epitaxial layer is formed using the susceptor. Accordingly, the entire surface of the semiconductor wafer facing the protruding portion can be etched uniformly. As a result, an epitaxial wafer with small variation in thickness can be manufactured.

In the susceptor for epitaxial layer forming apparatus according to the aspect of the invention, preferably, the diameter of the recessed portion is set to be a size allowing a semiconductor wafer with a diameter of 150 mm or less to be accommodated, the diameter of the protruding portion is set to be in a range of 50 mm to 90 mm, and the height of the protruding portion is set to 0.1 mm or more and less than 0.4 mm.

In this case, an epitaxial wafer with small variation in thickness and having a diameter of 150 mm or less can be manufactured.

If the diameter of the protruding portion is 50 mm or more, the semiconductor wafer can be stably held in the recessed portion, which is preferable. In addition, if the diameter of the protruding portion is 90 mm or less, it is possible to make reaction gas supplied for vapor-phase growth reaction circulate through the entire boundary between the protruding portion and the semiconductor wafer. As a result, the entire surface of the semiconductor wafer facing the protruding portion is etched uniformly, which is preferable.

Furthermore, if the height of the protruding portion is 0.1 mm or more, it is possible to make the reaction gas supplied for vapor-phase growth reaction circulate through the entire boundary between the protruding portion and the semiconductor wafer. As a result, the entire surface of the semiconductor wafer facing the protruding portion is etched uniformly, which is preferable. If the height of the protruding portion is less than 0.4 mm, the amount of reaction gas circulating through the entire boundary between the protruding portion and the semiconductor wafer does not become excessive and the semiconductor wafer is not etched partially. As a result, an epitaxial wafer with small variation in thickness can be manufactured.

In addition, it is preferable that the susceptor be formed of graphite in which a SiC layer is formed on a surface.

According to another aspect of the invention, an epitaxial layer forming apparatus includes: the susceptor for epitaxial layer forming apparatus described above; a layer forming chamber in which the susceptor is accommodated; and a heating unit that is provided at least on a side of the semiconductor wafer opposite the susceptor side.

In the epitaxial layer forming apparatus according to the aspect of the invention, an epitaxial wafer with small variation in thickness can be manufactured since the susceptor is provided.

According to another aspect of the invention, an epitaxial wafer includes an epitaxial layer formed on a semiconductor wafer. A thickness variation in the entire epitaxial wafer is equal to or smaller than ⅓ of a thickness of the epitaxial layer formed.

In the epitaxial wafer according to the aspect of the invention, the thickness variation is equal to or smaller than ⅓ of the formed epitaxial layer thickness, more preferably, equal to or smaller than ¼ of the formed epitaxial layer thickness. Accordingly, it is possible to increase the flatness compared with that in a known epitaxial wafer. Accordingly, a highly-integrated device can be formed on the epitaxial wafer.

In addition, in the epitaxial wafer according to the aspect of the invention, it is preferable that an impurity diffused layer be embedded between the semiconductor wafer and the epitaxial layer.

When the epitaxial wafer according to the aspect of the invention is a so-called embedded type epitaxial wafer in which an impurity diffused layer is embedded between a semiconductor wafer and an epitaxial layer, an epitaxial layer of the epitaxial wafer is formed at relatively high growth temperature. Accordingly, the etching amount of the surface of the semiconductor wafer facing the protruding portion does not become larger than that in a normal epitaxial wafer, and the variation in thickness is so small as to be ⅓ or less of the formed epitaxial layer thickness. As a result, a highly integrated device can be formed.

In a method of manufacturing an epitaxial wafer according to still another aspect of the invention, an epitaxial layer forming apparatus including the susceptor for epitaxial layer forming apparatus described above, a layer forming chamber in which the susceptor is accommodated, and a heating unit that is provided at least on a side of the semiconductor wafer opposite the susceptor side is prepared. In this method, a semiconductor wafer is accommodated in the recessed portion of the susceptor, reaction gas is supplied to the layer forming chamber while heating the semiconductor wafer using the heating unit, and the reaction gas is made to circulate between the protruding portion of the susceptor and the semiconductor wafer.

In the method of manufacturing an epitaxial wafer according to the aspect of the invention, since the reaction gas is made to circulate between the protruding portion and recessed portion of the susceptor and the semiconductor wafer when forming the epitaxial layer by using the epitaxial layer forming apparatus including the susceptor described above, the entire surface of the semiconductor wafer facing the protruding portion can be etched uniformly. As a result, an epitaxial wafer with small variation in thickness can be manufactured.

Furthermore, in the method of manufacturing an epitaxial wafer according to the aspect of the invention, a variation in flatness of each portion of each wafer used as each device can be made small by a subsequent device process. In particular, it becomes possible to make small a variation in flatness of each portion of a peripheral edge portion of a wafer.

### BRIEF DESCRIPTION OF THE DRAWINGS

FIG. 1 is a cross-sectional view showing an example of an epitaxial layer forming apparatus according to an embodiment of the invention;

FIG. 2 is a perspective view showing a susceptor for epitaxial layer forming apparatus according to an embodiment of the invention;

FIG. 3 is a partially sectional view taken along the line A-A of FIG. 2;

FIG. 4 is an enlarged sectional view showing main parts of the susceptor shown in FIG. 2;

FIGS. 5A to 5C are process views explaining a method of manufacturing an epitaxial wafer according to an embodiment of the invention;

FIG. 6 is a view showing main parts of the susceptor for epitaxial layer forming apparatus according to the embodiment of the invention, which is an enlarged sectional view illustrating the flow of reaction gas;

FIG. 7 is a cross-sectional view showing another example of the epitaxial layer forming apparatus according to the embodiment of the invention; and

FIGS. 8A to 8E are distribution views showing the distribution of the thickness of an epitaxial wafer.

### DETAILED DESCRIPTION OF THE INVENTION

Hereinafter, embodiments of the invention will be described with reference to the accompanying drawings. In addition, the drawings referred to in the following explanation are ones for describing the configuration of an epitaxial layer forming apparatus according to the present embodiment, and the size, thickness, and the like of each portion shown may be different from those in the actual apparatus.

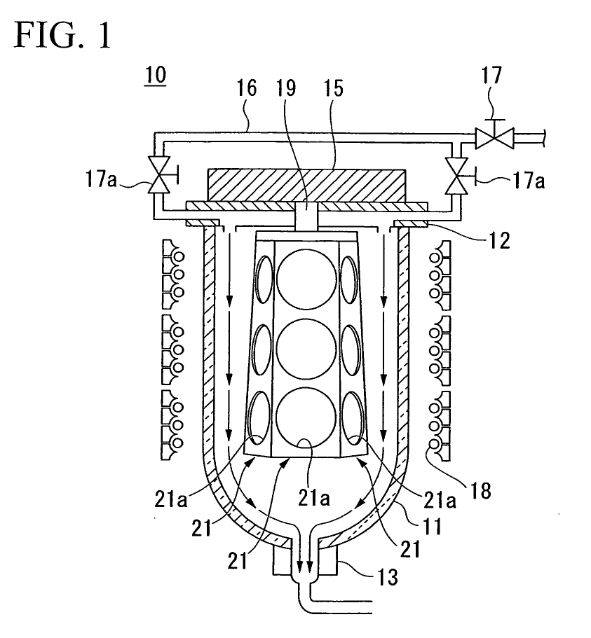

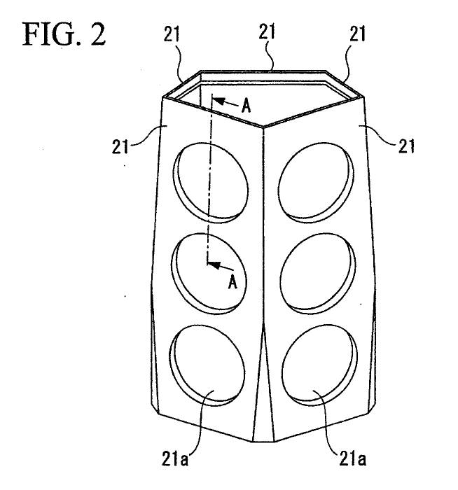

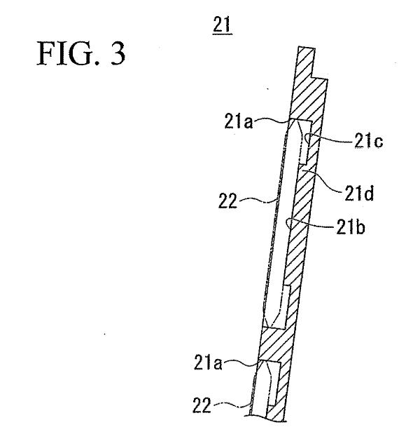

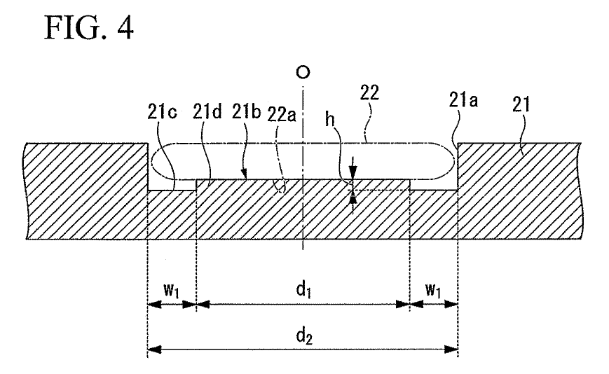

Hereinafter, an example of the epitaxial layer forming apparatus according to the present embodiment will be described with reference to FIGS. 1 to 4. FIG. 1 is a cross-sectional view showing an example of the epitaxial layer forming apparatus according to the present embodiment, and FIG. 2 is a perspective view showing a susceptor provided in the epitaxial layer forming apparatus. In addition, FIG. 3 is a partially sectional view taken along the line A-A of FIG. 2, and FIG. 4 is an enlarged sectional view showing main parts of the susceptor shown in FIG. 2. As shown in FIG. 1, an epitaxial layer forming apparatus 10 according to the present embodiment is a barrel type epitaxial layer forming apparatus. The epitaxial layer forming apparatus 10 has a bell jar 11, which is formed of quartz and serves as a layer forming chamber to which reaction gas is supplied, and a susceptor 21 provided inside the bell jar 11, and a heater 18 (heating unit) disposed around the bell jar 11.

A gas ring 12 formed of stainless steel in order to prevent reaction gas from leaking is disposed above the bell jar 11, and an exhaust flange 13 formed of stainless steel in order to discharge reaction gas therefrom is disposed below the bell jar 11. In addition, a top plate 15 for holding the bell jar 11 airtight is attached to the gas ring 12. In addition, a supply pipe 16 which communicates into the bell jar 11 through the gas ring 12 and serves to supply reaction gas is attached above the bell jar 11. A flow rate adjusting valve 17a and a main valve 17 which adjust the supply flow rate of reaction gas are disposed in the middle of the supply pipe 16.

With the configuration described above, reaction gas can be introduced into the bell jar 11 through the supply pipe 16 and exhaust gas and remaining reaction gas generated by vapor-phase growth reaction can be discharged from the bell jar 11 through the exhaust flange 13.

The heater 18 (heating unit) is disposed around the bell jar 11 as described above. The heater 18 is disposed opposite the susceptor 21 of a semiconductor wafer, which will be described later, with a peripheral wall portion of the bell jar 11 interposed therebetween.

The heater 18 raises the temperature of a semiconductor wafer to a predetermined growth temperature in forming an epitaxial layer. A lamp heater, such as halogen lamp, can be illustrated as a specific example of the heater 18.

The susceptor 21 in the invention is formed of graphite in which, for example, a SiC layer are formed on a surface. As shown in FIG. 1, the susceptor 21 is hung on approximately the same shaft within the bell jar 11 from an upper opening of the bell jar 11 through a hanger 19. As shown in FIGS. 1 and 2, the susceptor 21 has a five-cornered truncated shape where the diameter increases downward, and a plurality of (three in this example) recessed portions 21a each of which has an approximately circular shape and is able to accommodate a semiconductor wafer therein are formed on five peripheral faces of the susceptor 21. The inclination of each side surface of the susceptor 21 is preferably 1° or more and 10° or less from a vertical line.

In addition, as shown in FIGS. 3 and 4, one semiconductor wafer 22 can be accommodated in each of the recessed portions 21a of the susceptor 21. A silicon wafer formed of single crystal silicon can be exemplified as the semiconductor wafer 22. In addition, a groove 21c having an annular shape in plan view is formed in a peripheral edge portion of a bottom surface 21b of the recessed portion 21a. By formation of the groove 21c, a middle portion of the bottom surface 21b of the recessed portion protrudes relatively toward the semiconductor wafer 22 more than the bottom surface of the groove 21c. The protruding portion including the bottom surface 21b is assumed to be a protruding portion 21d in this specification. That is, the protruding portion 21d which has a circular shape in plan view and comes in contact with the semiconductor wafer 22 is provided in the recessed portion 21a of the susceptor.

The relationship between the recessed portion 21a and the protruding portion 21d will be described with reference to FIG. 4. A diameter in plan view d₁ of the protruding portion 21d is smaller than a diameter in plan view d₂ of the recessed portion 21a. In addition, the middle position of the recessed portion 21a and the middle position of the protruding portion 21d overlap a centerline O shown in FIG. 4. Furthermore, the diameter in plan view d₁ of the protruding portion 21d is set to be a size allowing reaction gas supplied for the vapor-phase growth reaction to circulate through the entire boundary between the protruding portion 21d (bottom surface 21b of the recessed portion) and the semiconductor wafer 22 when the semiconductor wafer 22 is placed in the recessed portion 21a.

In a known susceptor, a back surface of a semiconductor wafer, especially a peripheral edge portion was easily etched. Therefore, in a finished epitaxial wafer, the thickness of the peripheral edge portion was smaller than the thickness of the middle portion and a thickness variation in the entire epitaxial wafer was large. However, since the protruding portion 21d is provided in the recessed portion 21a in the susceptor 21 of the invention, the reaction gas supplied for the vapor-phase growth reaction may flow to the entire boundary between the protruding portion 21d (bottom surface 21b of the recessed portion) and the semiconductor wafer 22. As a result, since the middle portion of the epitaxial wafer is etched to the same extent as the peripheral edge portion such that the thickness of the middle portion is reduced to the same extent as the peripheral edge portion, it becomes possible to reduce the variation in the thickness of the entire wafer.

In order to make the reaction gas supplied for the vapor-phase growth reaction circulate through the entire boundary between the protruding portion 21d (bottom surface 21b of the recessed portion) and the semiconductor wafer 22, it is preferable to set the dimensional relationship between the recessed portion 21a and the protruding portion 21d as follows. That is, the diameter in plan view d₁ of the protruding portion 21d is preferably 25% or more and 85% or less of the diameter of a wafer, more preferably 30% or more and 60% or less. For example, in the case where the wafer is 150 mm or more and 153 mm or less, the diameter in plan view d₁ of the protruding portion 21d is preferably in a range of 50 mm to 90 mm. In addition, the diameter in plan view d₂ of the recessed portion 21a is a size allowing a semiconductor wafer equal to or smaller than 150 mm in diameter to be accommodated. More specifically, it is preferable that the diameter of the recessed portion be equal to or smaller than a size obtained by adding 150 mm to a clearance in which discharge of a semiconductor wafer from the recessed portion becomes easy. A value of (an inner diameter of the recessed portion 21a—an outer diameter of the wafer 22) is 1 mm or more and 5 mm or less, more preferably 1.5 mm or more and 3.5 mm or less. A width w₁ of the groove 21c is preferably in a range of 30 mm or more 50 mm or less. Furthermore, a height h of the protruding portion 21d, that is, a level difference between the bottom surface of the groove 21c and the bottom surface 21b of the recessed portion 21a is preferably in a range of equal to or larger than 0.1 mm and less than 0.4 mm.

If the diameter in plan view d₁ of the protruding portion 21d is 50 mm or more, the semiconductor wafer 22 can be stably held in the recessed portion 21a, which is preferable. In addition, if the diameter in plan view d₁ of the protruding portion 21d is 90 mm or less, it is possible to make reaction gas circulate through the entire boundary between the protruding portion 21d and the semiconductor wafer 22. As a result, an entire surface 22a of the semiconductor wafer 22 facing the protruding portion 21d is etched uniformly, which is preferable.

In addition, if the height h of the protruding portion 21d is 0.1 mm or more, it is possible to make reaction gas circulate through the entire boundary between the protruding portion 21d and the semiconductor wafer 22. As a result, the entire surface 22a of the semiconductor wafer 22 facing the protruding portion 21d is etched uniformly, which is preferable. If the height of the protruding portion 21d is less than 0.4 mm, the amount of reaction gas circulating through the entire boundary between the protruding portion 21d and the semiconductor wafer 22 does not become excessive. As a result, the semiconductor wafer 22 is not etched partially but an epitaxial wafer with small variation in thickness can be manufactured.

Moreover, from a point of view of allowing the reaction gas supplied for the vapor-phase growth reaction to circulate through the entire boundary between the protruding portion 21d and the semiconductor wafer 22, a surface roughness Ra of the bottom surface 21b of the recessed portion which is an upper surface of the protruding portion 21d is preferably in a range of 0.1 μm to 15 μm, more preferably, 1 μm to 5 μm. If the surface roughness is set equal to or larger than the lower limit, a small gap occurs between the bottom surface 21b and the surface 22a of the semiconductor wafer 22 facing the protruding portion 21d, such that the reaction gas can circulate between the bottom surface 21b and the surface 22a of the semiconductor wafer 22 facing the protruding portion 21d through the gap. In addition, occurrence of slip dislocation and the like of a semiconductor wafer can be prevented by setting the surface roughness equal to or smaller than the upper limit.

In addition, the surface roughness Ra of the bottom surface 21b of the recessed portion which is the upper surface of the protruding portion 21d may be in a range of 0.4 μm to 1 μm, in a range of 1 μm to 3 μm, or in a range of 8 μm to 12 μm.

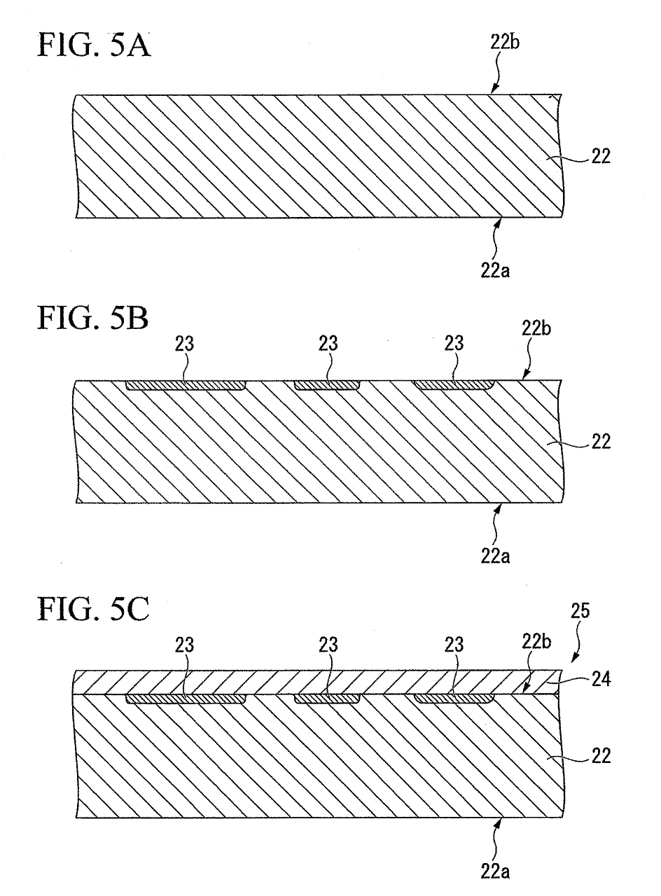

Next, a method of manufacturing an epitaxial wafer using the above epitaxial layer forming apparatus will be described. FIGS. 5A to 5C are process views explaining a method of manufacturing an epitaxial wafer according to the present embodiment.

First, as shown in FIG. 5A, the semiconductor wafer 22 is prepared. This semiconductor wafer 22 is a silicon wafer formed of single crystal silicon, as described above. The silicon wafer is a silicon wafer added with a P-type dopant.

Then, as shown in FIG. 5B, an impurity diffused layer 24 is formed on bottom surface 22b of the semiconductor wafer 22. The impurity diffused layer is formed by injecting and diffusing impurities, such as Sb, As, B, and P, into the bottom surface 22b of the semiconductor wafer 22 using an ion implantation technique. For example, an N⁺-type impurity diffused layer is formed by injecting P with high concentration.

Specifically, an oxide layer is formed on the entire bottom surface 22b after washing the bottom surface 22b of the semiconductor wafer 22. Then, the oxide layer is partially removed by etching a part of the oxide layer using a photolithography technique, thereby exposing the single crystal silicon. Then, for example, P (phosphorus) is ion-injected into the exposed single crystal silicon and is then annealed to thermally diffuse the P. Then, the oxide layer is removed, and an impurity diffused layer 23 shown in FIG. 5B is formed on bottom surface of the semiconductor wafer 22.

Then, the semiconductor wafer 22 after formation of the impurity diffused layer 23 is introduced into the epitaxial layer forming apparatus 10. When the semiconductor wafer 22 is accommodated in the recessed portion 21a of the susceptor 21, the semiconductor wafer 22 is accommodated such that the bottom surface 22b of the semiconductor wafer 22 is positioned toward a side opposite the protruding portion 21d. Accordingly, the surface 22a of the semiconductor wafer opposite the bottom surface is positioned facing the protruding portion 21d and comes in contact with the protruding portion 21d.

Then, an epitaxial layer is formed on the bottom surface 22b of the semiconductor wafer 22.

When forming the epitaxial layer starts, first, hydrogen gas is purged inside the bell jar 11 through the supply pipe 16 shown in FIG. 1, and the semiconductor wafer 22 is uniformly heated up to the desired growth temperature by raising the temperature of the inside of the bell jar 11 by the heater while rotating the susceptor 21 by a driving unit (not shown). The temperature inside the bell jar 11 is preferably raised in a range of 1000° C. to 1250° C., more preferably, in a range of 1150° C. to 1250° C. Then, for example, mixed gas of hydrogen chloride and hydrogen is supplied into the bell jar 11 through the supply pipe 16 to thereby etch the bottom surface 22b of the semiconductor wafer 22, and the inside of the bell jar 11 is purged again with hydrogen gas. In addition, the growth temperature in the range described above is a standard growth temperature in forming an embedded type epitaxial wafer. The growth temperature in manufacturing a normal epitaxial wafer may be lower than that in manufacturing the embedded type epitaxial wafer. Preferably, the growth temperature in manufacturing a normal epitaxial wafer is in a range of 1050° C. to 1170° C., for example.

After completing the etching process on the bottom surface 22b, mixed gas (reaction gas) obtained by adding silicon source gas, such as silicon tetrachloride, TCS (trichlorosilane), and dichlorosilane, to hydrogen gas which is carrier gas is supplied to the inside of the bell jar 11 through the supply pipe 16.

The reaction gas supplied to the inside of the bell jar 11 flows inside the bell jar 11 along an inner wall of the belljar 11 as indicated by the arrow of FIG. 1. By making the flowing reaction gas repeatedly pass above the bottom surface 22b of the semiconductor wafer 22 rotating with the susceptor 21, an epitaxial layer 24 grows on the bottom surface 22b of the semiconductor wafer 22 as shown in FIG. 5C.

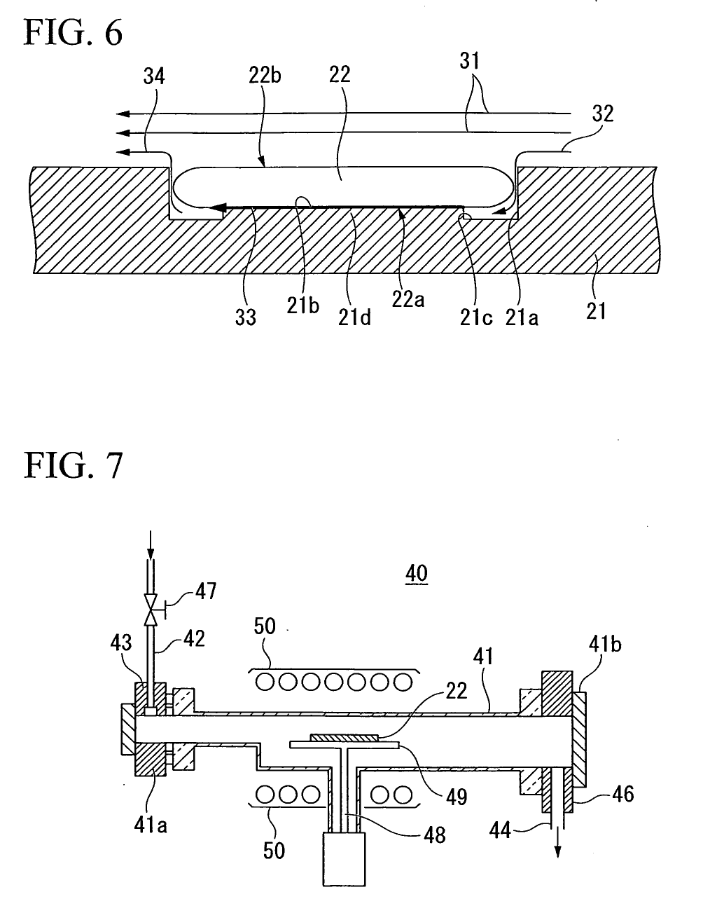

FIG. 6 is an enlarged sectional view schematically illustrating the flow of reaction gas near the susceptor 21 and the semiconductor wafer 22. As shown in FIG. 6, most of the reaction gas repeatedly passes above the bottom surface 22b of the semiconductor wafer 22 as indicated by arrow 31 of FIG. 6. In addition, as indicated by arrow 32, a part of the reaction gas turns from a gap between the recessed portion 21a and an outer peripheral portion of the semiconductor wafer 22 to a side of the surface 22a of the semiconductor wafer 22 opposite the bottom surface and then flows into the groove 21c. In addition, a part of the reaction gas that has flowed into the groove 21c circulates between the surface 22a of the semiconductor wafer 22 and the bottom surface 22b as indicated by arrow 33. Since the diameter in plan view d₁ of the protruding portion 21d is set to be a size allowing the reaction gas to circulate through the entire boundary between the protruding portion 21d and the semiconductor wafer 22, the reaction gas comes in contact with almost the entire surface of the surface 22a of the semiconductor wafer 22 opposite the bottom surface.

In the epitaxial layer forming apparatus according to the present embodiment, the temperature of the surface 22a of the semiconductor wafer 22 opposite the bottom surface 22b is relatively low compared with that of the bottom surface 22b since the heater 18 is disposed around the bell jar 11. For this reason, on the surface 22a of the semiconductor wafer 22 opposite the bottom surface 22b, the reaction gas which has flowed into the boundary between the semiconductor wafer 22 and the protruding portion 21d becomes in the etching atmosphere. As a result, almost the entire surface 22a of the semiconductor wafer 22 is etched uniformly.

In this manner, an epitaxial wafer 25 in which the epitaxial layer 24 is formed on the bottom surface 22b of the semiconductor wafer 22 is manufactured (FIG. 5C). In the case of the epitaxial wafer 25, a thickness variation in the entire wafer is preferably equal to or smaller than ⅓ of the formed epitaxial layer thickness, more preferably, equal to or smaller than ¼ of the formed epitaxial layer thickness or 5% of the formed epitaxial layer thickness. For example, a variation of 1% is 0.05 μm when the formed epitaxial layer thickness is 5 μm and 0.01 μm when the formed epitaxial layer thickness is 1 μm.

As described above, in the epitaxial layer forming apparatus 10 including the susceptor 21, the protruding portion 21d is provided in the recessed portion 21a in which the semiconductor wafer 22 is accommodated. Since the diameter d₁ of the protruding portion 21d of the susceptor 21 is set to be a size allowing the reaction gas to circulate through the entire boundary between the protruding portion 21d and the semiconductor wafer 22, it becomes possible to make the reaction gas exposed on the entire surface 22a of the semiconductor wafer 22 facing the protruding portion 21 d by forming the epitaxial layer using the susceptor 21. Accordingly, the entire surface 22a of the semiconductor wafer 22 facing the protruding portion is etched uniformly. As a result, the epitaxial wafer 25 with small variation in thickness can be manufactured.

In addition, since the diameter d₂ of the recessed portion 21a is 150 mm or less, the diameter d₁ of the protruding portion 21d is in a range of 50 mm to 90 mm, and the height h of the protruding portion 21d is 0.1 mm or more and less than 0.4 mm in the susceptor 21, an epitaxial wafer with small variation in thickness and having a diameter of 150 mm or less can be manufactured.

Furthermore, since the thickness variation in the epitaxial wafer 25 is equal to or smaller than ⅓ of the formed epitaxial layer thickness, the flatness is higher than that in a known epitaxial wafer. Accordingly, a highly integrated device can be formed on the epitaxial wafer.

In addition, the above-described epitaxial wafer is an embedded type epitaxial wafer in which the impurity diffused layer 23 is embedded between the semiconductor wafer 22 and the epitaxial layer 24. Since the epitaxial layer of the epitaxial wafer is formed at relatively high growth temperature, the etching amount of the surface 22a of the semiconductor wafer 22 facing the protruding portion becomes larger than that in a normal epitaxial wafer. However, the variation in thickness becomes ⅓ or less of the formed epitaxial layer thickness, which is smaller than that in a known epitaxial wafer. Accordingly, a highly integrated device can be formed.

Furthermore, in the method of manufacturing the epitaxial wafer, reaction gas is made to also circulate between the recessed portion 21a and the protruding portion 21d of the susceptor 21 and the semiconductor wafer 22 in forming the epitaxial layer. Accordingly, the entire surface 22a of the semiconductor wafer 22 facing the protruding portion can be etched uniformly. As a result, the epitaxial wafer 25 with small variation in thickness can be manufactured.

In addition, it should be understood that the technical scope of the invention is not limited to the above embodiments, but various modifications may be made without departing from the spirit and scope of the invention.

Although the embedding type epitaxial wafer has been described in the present embodiment, the invention is not limited thereto, but may also be suitably applied to a normal epitaxial wafer not having an impurity diffused layer.

In addition, the susceptor of the present embodiment is not limited to a barrel type epitaxial layer forming apparatus, but may also be applied to a single wafer type epitaxial layer forming apparatus.

FIG. 7 is a schematic view illustrating a single wafer type epitaxial layer forming apparatus. An epitaxial layer forming apparatus 40 shown in FIG. 7 includes: a quartz chamber 41 having a layer forming chamber formed thereinside; an injection flange 43 which connects a supply pipe 42 to the quartz chamber 41; an exhaust flange 46 which connects an exhaust pipe 44 to the quartz chamber 41; a main valve 47 provided in the middle of the supply pipe 42; and an output port 41a for wafer transport and a thermocouple fixed flange 41b which are provided in openings on both sides of the quartz chamber 41. In addition, a lamp heater 50 (heating unit) is provided above and below the quartz chamber 41.

A supporting plate 48 is provided passing through a lower portion of the quartz chamber 41 such that an upper end edge is positioned within the quartz chamber 41, and a susceptor 49 is provided approximately horizontally with respect to the upper end edge of the supporting plate 48.

Also in the susceptor 49 used in the single wafer type epitaxial layer forming apparatus 40 shown in FIG. 7, the same effects as the susceptor 21 and the epitaxial layer forming apparatus 10 can be obtained by providing a recessed portion and providing a protruding portion in the recessed portion similar to the susceptor 21 described earlier.

### EXAMPLES

A P-type silicon wafer which is doped with P-type dopant and is 150 mm in diameter was prepared, and an epitaxial layer was formed on the P-type silicon wafer in the following procedures.

The epitaxial layer forming apparatus shown in FIG. 1 was prepared, and the P-type silicon wafer was accommodated in a recessed portion of a susceptor of the apparatus. Then, hydrogen gas was purged inside a bell jar, and the P-type silicon wafer was heated uniformly by raising the inside of the bell jar up to a temperature of 1220° with the heater while rotating the susceptor.

Then, an epitaxial layer having a thickness of 9 μm was grown by supplying reaction gas, which is obtained by adding silicon source gas of TCS (trichlorosilane) to hydrogen gas with a concentration rate of 5%, inside the bell jar by a flow rate of 150 ml/min.

Moreover, in the above process, the diameter of the recessed portion of the susceptor was set to about 150 mm, the width of the groove was set to 2 to 40 mm (the diameter of the protruding portion was set to 70 to 146 mm), and the height of the protruding portion was set to 0.2 to 0.4 mm.

In addition, a susceptor in which another recessed portion with a depth of 0.2 mm and a diameter of 110 mm is further provided in the recess was also used. In the case of the susceptor, a peripheral edge portion of a semiconductor wafer is supported by a bottom surface of the recessed portion.

For the manufactured epitaxial wafer, a difference of TTV (total thickness variation) before and after forming the epitaxial layer was measured, and the difference of TTV was confirmed as the thickness variation before and after forming the epitaxial layer.

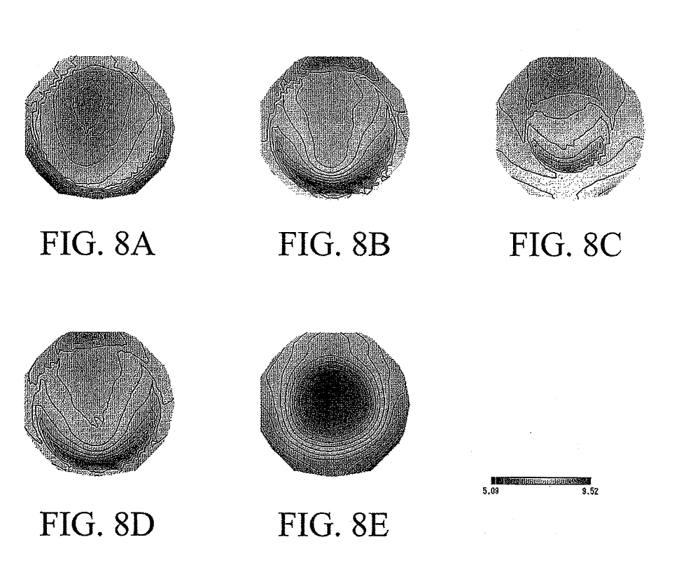

The thickness variation is shown in a table 1, and a measurement result of TTV is shown in FIGS. 8A to 8E. In addition, No. 1 in the table 1 corresponds to FIG. 8A, No. 2 in the table 1 corresponds to FIG. 8B, No. 3 in the table 1 corresponds to FIG. 8C, No. 4 in the table 1 corresponds to FIG. 8D, and No. 4 in the table 1 corresponds to FIG. 8E. The thickness variation in table 1 is an average of difference data of TTV on the entire wafer surface.

TABLE 1

| | | | | Diameter and | |
|---|---|---|---|---|---|
| | | Diameter of | Height of | depth of another | |
| | Width of | protruding | protruding | recessed | Variation in |
| No. | groove (mm) | portion (mm) | portion (mm) | portion (mm) | thickness (μm) |
| 1 | — | — | — | Width 20 mm | 3.45 |
| | | | | Depth 0.2 mm | |
| 2 | 20 | 110 | 0.4 | — | 3.95 |
| 3 | 40 | 70 | 0.2 | — | 2.97 |
| 4 | 20 | 110 | 0.2 | — | 3.61 |
| 5 | 2 | 146 | 0.2 | — | 3.97 |

From the table 1, it can be seen that the variation in thickness is relatively small in a case (No. 3) where the diameter of a protruding portion is 70 mm and the height of the protruding portion is 0.2 mm.

In addition, it can be seen that in a case (No. 5) where the diameter of a protruding portion is 146 mm or cases (Nos. 2 and 4) where the diameter of a protruding portion is 110 mm, the variation in thickness is larger than that of No. 3.

Furthermore, in a wafer (No. 1) manufactured by using the susceptor in which another recessed portion is provided in a recessed portion, it can be seen that the variation in thickness is larger than that of No. 3.

Then, from FIG. 8C, it can be seen that a variation in distribution of TTV is relatively low. On the other hand, from FIGS. 8A, 8B, 8D, and 8E, it can be seen that the variation in distribution of TTV is relatively high. Particularly in the case of a wafer shown in FIG. 8E, it can be seen that the etching amount in a middle portion is extremely small. Assumedly, this is because reaction gas did not sufficiently circulate through the middle portion of the wafer due to the diameter of the protruding portion set too large and accordingly, only the peripheral edge portion was etched to thereby increase the variation.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A susceptor for epitaxial layer forming apparatus provided in a layer forming chamber of an epitaxial layer forming apparatus, comprising:
a recessed portion which is provided to accommodate a semiconductor wafer therein and has an approximately circular shape in plan view; and
a protruding portion which is provided in the recessed portion in order to support the semiconductor wafer and has an approximately circular shape in plan view,
wherein the diameter of the protruding portion is smaller than that of the recessed portion, and
the diameter of the protruding portion is set to be a size allowing reaction gas supplied for vapor-phase growth reaction to circulate through an entire boundary between the protruding portion and the semiconductor wafer when the semiconductor wafer is placed in the recessed portion.

2. The susceptor for epitaxial layer forming apparatus according to claim 1,
wherein the diameter of the recessed portion is set to be a size allowing a semiconductor wafer with a diameter of 150 mm or less to be accommodated,
the diameter of the protruding portion is set to be in a range of 50 mm to 90 mm, and
the height of the protruding portion is set to 0.1 mm or more and less than 0.4 mm.

3. An epitaxial layer forming apparatus, comprising:
the susceptor for epitaxial layer forming apparatus according to claim 1;
a layer forming chamber in which the susceptor is accommodated; and
a heating unit that is provided at least on a side of the semiconductor wafer opposite the susceptor side.

4. An epitaxial wafer comprising:
an epitaxial layer formed on a semiconductor wafer,
wherein a variation in wafer thickness as a difference between thicknesses before and after forming the epitaxial layer is set to be equal to or smaller than ⅓ of a thickness of the epitaxial layer formed.

5. The epitaxial wafer according to claim 4,
wherein an impurity diffused layer is embedded between the semiconductor wafer and the epitaxial layer.

6. A method of manufacturing an epitaxial wafer, comprising:
preparing an epitaxial layer forming apparatus including the susceptor for epitaxial layer forming apparatus according to claim 1, a layer forming chamber in which the susceptor is accommodated, and a heating unit that is provided at least on a side of the semiconductor wafer opposite the susceptor side;
accommodating a semiconductor wafer in the recessed portion of the susceptor;
heating the semiconductor wafer using the heating unit;
supplying reaction gas to the layer forming chamber simultaneously with the heating; and
making the reaction gas circulate between the protruding portion of the susceptor and the semiconductor wafer simultaneously with the supplying of the reaction gas.

7. An epitaxial layer forming apparatus, comprising:
the susceptor for epitaxial layer forming apparatus according to claim 2;
a layer forming chamber in which the susceptor is accommodated; and
a heating unit that is provided at least on a side of the semiconductor wafer opposite the susceptor side.

8. A method of manufacturing an epitaxial wafer, comprising:
preparing an epitaxial layer forming apparatus including the susceptor for epitaxial layer forming apparatus according to claim 2, a layer forming chamber in which the susceptor is accommodated, and a heating unit that is provided at least on a side of the semiconductor wafer opposite the susceptor side;
accommodating a semiconductor wafer in the recessed portion of the susceptor;
heating the semiconductor wafer using the heating unit;
supplying reaction gas to the layer forming chamber simultaneously with the heating; and
making the reaction gas circulate between the protruding portion of the susceptor and the semiconductor wafer simultaneously with the supplying of the reaction gas.
